(19) United States
(12) Patent Application Publication
(10) Pub. No.: US 2022/0069756 A1
(43) Pub. Date: Mar. 3, 2022

(54) FAN MANAGEMENT METHOD AND SYSTEM, AND SERVER

(71) Applicants: Inventec (Pudong) Technology Corporation, Shanghai (CN); INVENTEC CORPORATION, Taipei (TW)

(72) Inventors: Shuaifeng ZHU, Shanghai (CN); Hai-tao FANG, Shanghai (CN); Lian-fei ZHANG, Shanghai (CN); Qi LIU, Shanghai (CN)

(73) Assignees: Inventec (Pudong) Technology Corporation, Shanghai (CN); INVENTEC CORPORATION, Taipei (TW)

(21) Appl. No.: 17/137,395

(22) Filed: Dec. 30, 2020

(30) Foreign Application Priority Data
Aug. 27, 2020 (CN) 2020108808642

(51) Int. Cl. H02P 29/00; H02P 5/00; G01K 13/00; G01P 3/00

(52) U.S. Cl. CPC H02P 29/00; H02P 5/00; H05K 7/20754; G01P 3/00; G01K 13/00

(57) ABSTRACT

The present disclosure provides a fan management method and system, and a server. The method includes: monitoring working performance of each dual-motor fan in real-time; determining whether the working performance of the dual-motor fan is normal, if the working performance is normal, instructing the dual-motor fan to continue to operate with normal performance; if the working performance is not normal, instructing a single-motor fan that has no abnormality in the dual-motor fan to operate with a preset compensation strategy; the preset compensation strategy is a strategy for performing performance compensation for a single-motor fan that has no abnormality to normal performance of a dual-motor fan. The present disclosure can reduce energy consumption of the server, avoid ineffective waste, and save operating costs. The fan can be prevented from running at a high speed for a long time, and the service life of the fan can be improved.

### CROSS REFERENCE TO RELATED APPLICATION

The present application is related to and claims the benefit of priority to Chinese Patent Application No. 2020108808642, entitled “Fan Management Method and System, and Server”, filed with CNIPA on Aug. 27, 2020, the contents of which are incorporated herein by reference in its entirety.

### BACKGROUND

### Field of Disclosure

The present disclosure relates to the technical field of fan control of servers, and relates to a management method, in particular to a fan management method and system, and a server.

### Description of Related Arts

In the heat dissipation design of servers, to save energy consumption and control server noise at the same time, a fan control design is usually performed. Generally, servers need to support N+1 redundancy design of fans, and multiple dual-motor fans will be used. When the fan is working normally, the system will adjust the speed according to the preset strategy according to the ambient temperature and device temperature. When the fan fails, the system will increase the fan speed to a higher speed, such as 80% or 100% duty.

Although the traditional strategies can effectively solve the system heat dissipation problem caused by fan failure, there are problems of excessive heat dissipation, serious waste of system energy consumption, and excessive noise.

Therefore, how to provide a fan management method and system, and a server to solve the defects of the prior art such as excessive heat dissipation, serious waste of system energy consumption, excessive noise, etc., has actually become a technical problem to be solved by those skilled in the art.

### SUMMARY

The present disclosure provides a fan management method and system, and a server, to solve the problems of excessive heat dissipation, serious waste of system energy consumption, and excessive noise in the prior art.

The present disclosure provides a fan management method applied to a server, and the server includes a plurality of dual-motor fans; the method includes: monitoring working performance of each of the plurality of dual-motor fans in real-time; determining whether the working performance of the dual-motor fan is normal, if the working performance is normal, instructing the dual-motor fan to continue to operate with normal performance; if the working performance is not normal, instructing a single-motor fan that has no abnormality in the dual-motor fan to operate with a preset compensation strategy; the preset compensation strategy is a strategy for performing performance compensation for a single-motor fan that has no abnormality to normal performance of a dual-motor fan.

In an embodiment of the present disclosure, the working performance of the dual-motor fan includes a speed and/or a duty cycle of the single-motor fan in the dual-motor fan.

In an embodiment of the present disclosure, the monitoring of the working performance of the dual-motor fan in real-time includes: monitoring an ambient temperature and a temperature of an internal component of the server in real-time by a management unit of the server; and calculating a speed of the dual-motor fan according to the ambient temperature and the temperature of the internal component of the server by the management unit of the server.

In an embodiment of the present disclosure, the internal component of the server includes a processor, a memory, and a dual in-line memory module.

In an embodiment of the present disclosure, a calculation method for calculating the speed of the single-motor fan includes: any one or a combination of a linear speed control method and a proportional-integral-derivative speed control method.

In an embodiment of the present disclosure, the determining of whether the working performance of the dual-motor fan is normal includes: comparing the speed of each single-motor fan in the dual-motor fan with a preset speed threshold; when the speed of each single-motor fan is greater than the preset speed threshold, the working performance of the dual-motor fan is normal; when the speed of a single-motor fan is less than or equal to the preset speed threshold, the working performance of the dual-motor fan is abnormal.

In an embodiment of the present disclosure, the preset compensation strategy includes: superimposing the duty cycle of the single-motor fan under normal performance with a preset compensation duty cycle to obtain a compensated duty cycle; and running the single-motor fan with no abnormality in the dual-motor fan with the compensated duty cycle.

In an embodiment of the present disclosure, the preset compensation duty cycle is 20%-40% of the duty cycle under normal performance.

The present disclosure further provides a fan management system applied to a server; the system includes: a management module, configured to monitor working performance of each of the plurality of dual-motor fans in real-time; a processing module, configured to determine whether the working performance of the dual-motor fan is normal, if the working performance is normal, instructing the dual-motor fan to continue to operate with normal performance; if the working performance is not normal, instructing a single-motor fan that has no abnormality in the dual-motor fan to operate with a preset compensation strategy; the preset compensation strategy is a strategy for performing performance compensation for a single-motor fan that has no abnormality to normal performance of a dual-motor fan.

The present disclosure further provides a server, including: a plurality of dual-motor fans for dissipating heat of the server, a processor and a memory; the memory stores a computer program, and the processor executes the computer program stored in the memory, causes the server to implement the above fan management method.

As described above, the fan management method and system, and the server of the present disclosure have the following beneficial effects:

First, the present disclosure can reduce energy consumption of the server, avoid waste, and save operating costs.

Second, the present disclosure can reduce server noise and improve user experience.

Third, the present disclosure can prevent the fan of server from running at a high speed for a long time and improve the service life of the fan.

### BRIEF DESCRIPTION OF THE DRAWINGS

FIG. 1 shows a schematic view of a P-Q curve and a system impedance curve of an 8056 dual-motor fan under different duty cycles according to the present disclosure.

FIG. 2 shows a schematic view of the fundamental structure of a server applied in the present disclosure.

FIG. 3 shows a schematic flowchart of a fan management method according to an embodiment of the present disclosure.

FIG. 4 shows a schematic view of the fundamental structure of a fan management system according to an embodiment of the present disclosure.

### DESCRIPTION OF COMPONENT MARK NUMBERS

2 Server
21 Dual-motor fan
211 Single-motor fan
4 Fan management system
41 Management module
42 Processing module
420 Determining unit
421 First instruction unit
422 Second instruction unit
S31 to S34 Operations

### DETAILED DESCRIPTION OF THE PREFERRED EMBODIMENTS

The embodiments of the present disclosure will be described below through exemplary embodiments. Those skilled in the art can easily understand other advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure. It needs to be stated that the following embodiments and the features in the embodiments can be combined with one another under the situation of no conflict.

It needs to be stated that the drawings provided in the following embodiments are just used for schematically describing the basic concept of the present disclosure, thus only illustrating components only related to the present disclosure and are not drawn according to the numbers, shapes and sizes of components during actual implementation, the configuration, number and scale of each component during actual implementation thereof may be freely changed, and the component layout configuration thereof may be more complex.

The technical principles of the fan management method and system, and the server of the present disclosure are as follows:

The server system includes a plurality of dual-motor fans, when the dual-motor fans work normally, they run with normal working performance PWM1. When a single-motor fan of a dual-motor fan fails, the performance will decrease. By increasing a certain speed of the other single-motor fan to PWM2, the performance of the other single-motor fan is similar to PWM1, to compensate for the decrease in heat dissipation capacity due to fan failure.

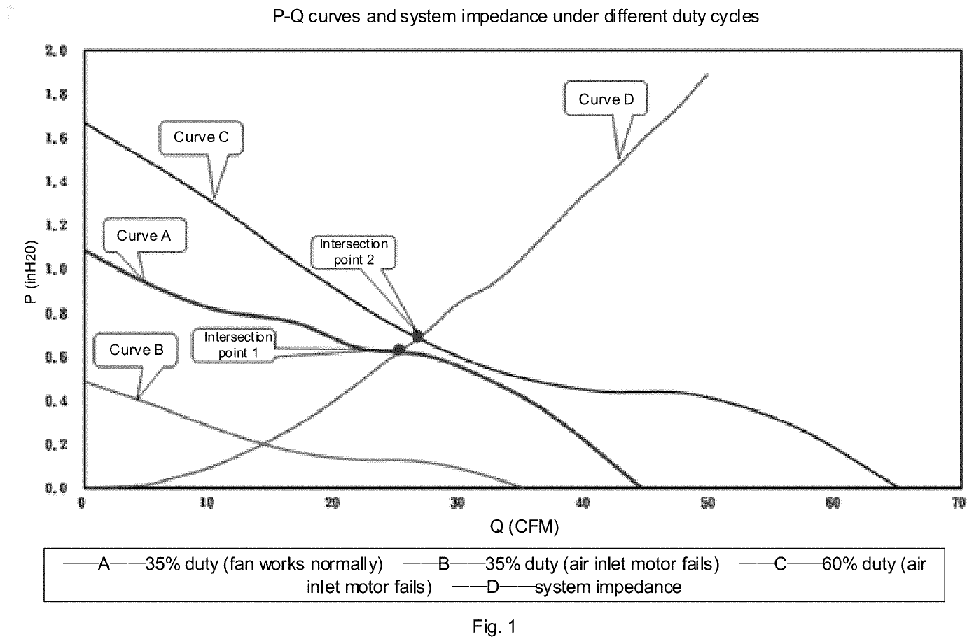

Referring to FIG. 1, which shows a schematic view of a P-Q curve and a system impedance curve of an 8056 dual-motor fan under different duty cycles according to the present disclosure. As shown in FIG. 1, curve A is a P-Q curve when the fan is working normally at 35% duty cycle, curve B is a P-Q curve when the air inlet motor fails at 35% duty cycle, curve C is a P-Q curve when the air inlet motor fails at 60% duty cycle, and curve D is a system impedance curve. The intersection point 1 of curve A and curve D represents the operating point when the fan is working normally at 35% duty cycle, and the intersection point 2 of curve C and curve D represents the operating point when the fan fails at 60% duty cycle.

It can be seen from FIG. 1 that the intersection point 1 and intersection point 2 are close, which indicates that the fan management method of the present disclosure increases the speed of the failed fan to 60%, which can achieve the performance when the fan is working normally at 35% duty cycle, and the heat dissipation capacity of the system is not reduced.

### Embodiment 1

This embodiment provides a fan management method, which is applied to a server, and the server includes a plurality of dual-motor fans; the method includes: monitoring working performance of each of the plurality of dual-motor fans in real-time; determining whether the working performance of the dual-motor fan is normal, if the working performance is normal, instructing the dual-motor fan to continue to operate with normal performance; if the working performance is not normal, instructing a single-motor fan that has no abnormality in the dual-motor fan to operate with a preset compensation strategy; the preset compensation strategy is a strategy for performing performance compensation for a single-motor fan that has no abnormality to normal performance of a dual-motor fan.

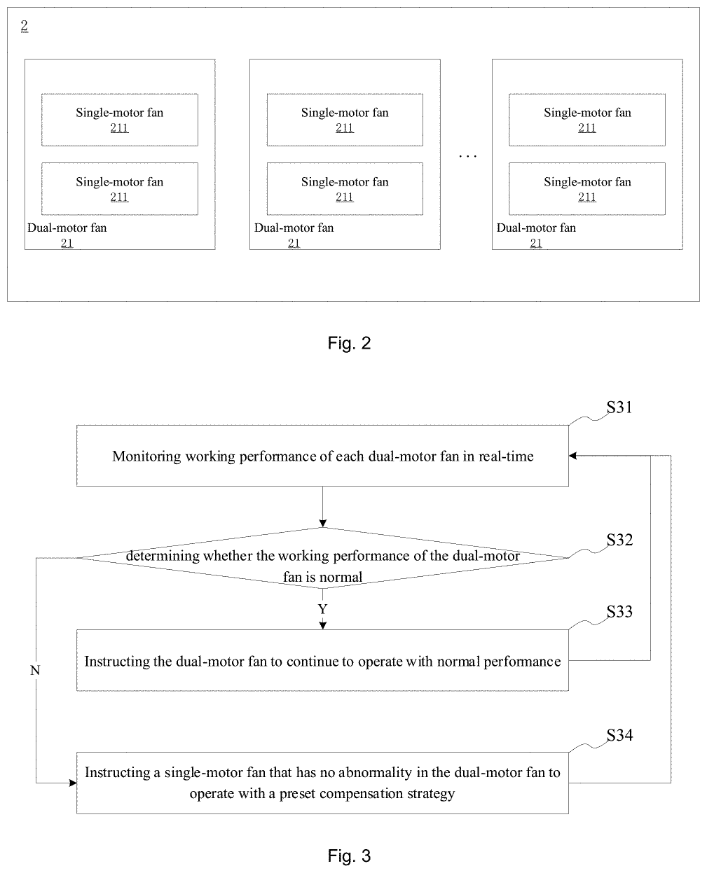

The fan management method provided in this embodiment will be described in detail below with reference to the drawings. The fan management method described in this embodiment is applied to the server 2 shown in FIG. 2 to manage the plurality of dual-motor fans 21 configured on the server 2. The dual-motor fan 21 includes two single-motor fans 211 arranged in parallel, and the two single-motor fans can rotate under the control of the same PWM (Pulse Width Modulation) signal to efficiently perform heat dissipation management inside the server.

Referring to FIG. 3, which shows a schematic flowchart of the fan management method in an embodiment. As shown in FIG. 3, the fan management method includes the following operations:

S31: monitoring working performance of each of the plurality of dual-motor fans in real-time. In this embodiment, the working performance of the dual-motor fan includes a speed and/or a duty cycle of the single-motor fan in the dual-motor fan.

In this embodiment, the operation S31 includes:

S311: monitoring an ambient temperature and a temperature of an internal component of the server in real-time by a management unit of the server.

Specifically, the management unit of the server is coupled with a temperature sensor at the air inlet of the server through an I2C interface, so as to obtain the temperature at the air inlet in real-time.

Specifically, the management unit of the server reads the temperature values detected by temperature sensors integrated in some components through I2C or SMBus. The internal component of the server includes a processor, a memory, and a dual in-line memory module.

The management unit of the server may be a BMC baseboard management controller or a Complex Programmable Logic Device (CPLD).

S312: calculating a speed of the dual-motor fan according to the ambient temperature and the temperature of the internal component of the server by the management unit of the server.

In this embodiment, a calculation method for calculating the speed of the single-motor fan includes: any one or a combination of a linear speed control method and a proportional-integral-derivative speed control method.

For example, the PID algorithm is a commonly used control algorithm: by monitoring the real-time temperature value (Tj) of the heating devices and temperature sensors, and then setting a target desired temperature value (SP value or Setpoint) for each of the heating devices and temperature sensors, the deviation e(t) between the real-time temperature value (Tj) and the desired temperature value (Setpoint value) can be calculated. The PID controller can output a correction action and correction value, that is, the PWM value signal that the fan needs to adjust, to the fan to adjust the fan's PWM and speed, thereby adjusting the real-time temperature (Tj) of the heating device, to reduce the deviation value e(t)=SP-Tj between the real-time temperature (Tj) and the Setpoint value of the desired temperature, so that the temperature of all the heating devices eventually tends to the set desired value (Setpoint value). In general PID fan regulation, for each temperature sensor (including the internal sensor of the heating device and the temperature sensor arranged on the server board), a fixed value is usually set as the SP value of its temperature regulation, namely the inflection point of the fan control, which is used as the expected value in the PID control process.

S32: determining whether the working performance of the dual-motor fan is normal; if the working performance is normal, executing the operation S23; if the working performance is not normal, executing the operation S24. In this embodiment, the working performance of the dual-motor fan includes a speed and/or a duty cycle of the single-motor fan in the dual-motor fan.

Specifically, the operation S32 includes: comparing the speed of each single-motor fan in the dual-motor fan with a preset speed threshold; when the speed of each single-motor fan is greater than the preset speed threshold, the working performance of the dual-motor fan is normal; when the speed of a single-motor fan is less than or equal to the preset speed threshold, the working performance of the dual-motor fan is abnormal.

S33: if the working performance of the dual-motor fan is normal, instructing the dual-motor fan to continue to operate with normal performance. For example, the single-motor fan in the dual-motor fan operates normally with the duty cycle of PWM1.

S34: if the working performance of the dual-motor fan is not normal, instructing a single-motor fan that has no abnormality in the dual-motor fan to operate with a preset compensation strategy. In this embodiment, the preset compensation strategy is a strategy for performing performance compensation for a single-motor fan that has no abnormality to normal performance of a dual-motor fan.

The preset compensation strategy includes: superimposing the duty cycle of the single-motor fan under normal performance with a preset compensation duty cycle to obtain a compensated duty cycle; and running the single-motor fan with no abnormality in the dual-motor fan with the compensated duty cycle, that is, the compensated duty cycle PWM2=the duty cycle PWM1 of the single-motor fan under normal performance+preset compensation duty cycle A. The preset compensation duty cycle A is 20%-40% of the duty cycle under normal performance. The value of the preset compensation duty cycle A can be optimized and adjusted according to different fan sizes, models, systems, etc., to achieve better performances.

The fan management method described in this embodiment is applied to a 2U server to compare the test data:

Test item 1: 25C fan works normally, the speed of all fans is 38%, and the system is fully loaded with test data;

Test item 2: 25C single-motor fan fails (single-motor fan 2_F Motor fails), the speed of all fans is 100% duty cycle, and the system is fully loaded with test data;

Test item 3: 25C single-motor fan fails (single-motor fan 2_F Motor fails), the speed of single-motor fans is 78% duty cycle, the speed of other fans is 38% duty cycle, and the system is fully loaded with test data.

The fan management method described in this embodiment is applied to test items 2 and 3, a preset compensation strategy is used, the fan speed is greatly reduced, which can effectively reduce system energy consumption (˜224 W), while ensuring that the heat dissipation of the system is not significantly reduced. Specific test data comparison is shown in table 1.

The fan management method described in this embodiment is applied to test item 3, and test item 3 is compared with test item 1, it can be seen that test item 3 adopts a preset compensation strategy, the temperature of the components in the system is basically the same, and the heat dissipation capacity is basically the same.

TABLE 1
Test data comparison
Test configuration: CPU 165W *2 + DDR4 32G *24 + 3.84T U.2
SSD *4 + MOC 1.5 *1 + 8056 Fan *4 +800W PSU *2

| Test items | | 1 | 2 | 3 |
|---|---|---|---|---|
| Performance/power consumption | | 100% | 100% | 100% |
| ratio benchmark test (CPU & | | | | |
| DDR4) | | | | |
| Fan status | | Fan | Fan2_F | Fan2_F |
| | | works | Motor | Motor |
| | | normally | failed | failed |
| System fan 1 PWM (%) | | 38% | 100% | 38% |
| System fan 2 PWM (%) | | 38% | 100% | 78% |
| System fan 3 PWM (%) | | 38% | 100% | 38% |
| System fan 4 PWM (%) | | 38% | 100% | 38% |
| Server power consumption (read | | 648 | 880 | 656 |
| by BMC) | | | | |
| Fan 1_ R_ RPM | | 5280 | 13360 | 5280 |
| Fan 1_F_RPM | | 6160 | 15760 | 6160 |
| Fan 2 _ R_ RPM | | 5280 | 13520 | 10960 |
| Fan 2_F_RPM | | 6240 | 0 | 0 |
| Fan 3_ R_ RPM | | 5200 | 13600 | 5280 |
| Fan 3_F_RPM | | 6080 | 15920 | 6080 |
| Fan 4_R_RPM | | 5200 | 13680 | 5200 |
| Fan 4_F_RPM | | 6000 | 15840 | 6080 |
| read by BMC temperature sensor | SPEC | | | |
| Temperature at inlet | N/A | 26 | 25 | 26 |
| CPU0_temperature | 88 | 62 | 55 | 62 |
| CPU1_temperature | 88 | 59 | 49 | 58 |
| Total power consumption | N/A | 648 | 880 | 656 |
| MOC1_CPU_temperature | 95 | 53 | 39 | 49 |
| MOC1_FPGA_temperature | 100 | 64 | 48 | 61 |
| p | | | | |
| MOC1_DIMM_temperature | 85 | 47 | 36 | 44 |
| read by MOC temperature sensor | SPEC | | | |
| 25G SFP + 1 | 70 | 45.48 | 36.44 | 43.99 |
| 25G SFP + 2 | 70 | 45.43 | 36.11 | 43.70 |
| DIMM0_temperature | 85 | 44 | 34 | 50 |
| DIMM1_temperature | 85 | 47 | 36 | 44 |
| CPU_temperature | 95 | 53 | 40 | 49 |
| FPGA_temperature | 100 | 64 | 48 | 61 |
| MLNX_temperature | 105 | 61 | 47 | 51 |

The fan management method described in this embodiment has the following beneficial effects:

First, the fan management method described in this embodiment can reduce energy consumption of the server, avoid waste, and save operating costs.

Second, the fan management method described in this embodiment can reduce noise of the server and improve user experience.

Third, the fan management method described in this embodiment can prevent the fan of server from running at a high speed for a long time and improve the service life of the fan.

### Embodiment 2

This embodiment provides a fan management system applied to a server; the system includes: a management module, configured to monitor working performance of each of the plurality of dual-motor fans in real-time; a processing module, configured to determine whether the working performance of the dual-motor fan is normal, if the working performance is normal, instructing the dual-motor fan to continue to operate with normal performance; if the working performance is not normal, instructing a single-motor fan that has no abnormality in the dual-motor fan to operate with a preset compensation strategy; the preset compensation strategy is a strategy for performing performance compensation for a single-motor fan that has no abnormality to normal performance of a dual-motor fan.

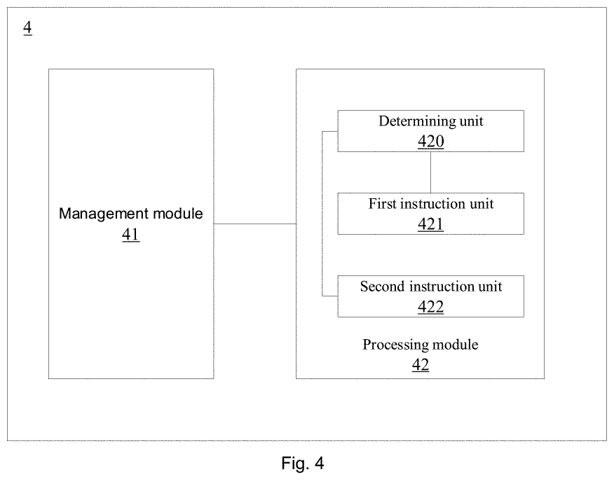

The fan management system provided in this embodiment will be described in detail below with reference to the drawings. Referring to FIG. 4, which shows a schematic view of the fundamental structure of the fan management system in an embodiment. As shown in FIG. 4, the fan management system 4 includes a management module 41 and a processing module 42.

The management module 41 monitors the working performance of each dual-motor fan in real-time. In this embodiment, the working performance of the dual-motor fan includes a speed and/or a duty cycle of the single-motor fan in the dual-motor fan.

In this embodiment, the management module 41 monitors an ambient temperature and a temperature of an internal component of the server in real-time.

Specifically, the management unit 41 of the server is coupled with a temperature sensor at the air inlet of the server through an I2C interface, to obtain the temperature at the air inlet in real-time.

Specifically, the management unit 41 of the server reads the temperature values sensed by temperature sensors integrated in some components through I2C or SMBus. The internal component of the server includes a processor, a memory, and a dual in-line memory module.

The management module 41 calculates a speed of the dual-motor fan according to the ambient temperature and the temperature of the internal component of the server.

In this embodiment, a method for calculating the speed of the single-motor fan includes: any one or a combination of a linear speed control method and a proportional-integral-derivative speed control method.

The processing module 42 coupled with the management module 41 determines whether the working performance of the dual-rotor fan is normal; if the working performance is normal, the dual-motor fan is instructed to continue to operate with normal performance; if the working performance is not normal, a single-motor fan that has no abnormality in the dual-motor fan is instructed to operate with a preset compensation strategy; In this embodiment, the working performance of the dual-motor fan includes a speed and/or a duty cycle of the single-motor fan in the dual-motor fan.

Specifically, the processing module 42 includes a determining unit 420, a first instruction unit 421, and a second instruction unit 422.

Specifically, the determining unit 420 compares the speed of each single-motor fan in the dual-motor fan with a preset speed threshold; when the speed of each single-motor fan is greater than the preset speed threshold, the working performance of the dual-motor fan is normal; when the speed of a single-motor fan is less than or equal to the preset speed threshold, the working performance of the dual-motor fan is abnormal.

When the working performance of the dual-motor fan is normal, the first instruction unit 421 instructs the dual-motor fan to continue to operate with the normal performance. For example, the single-motor fan in the dual-motor fan operates normally with the duty cycle of PWM1.

When the working performance of the dual-motor fan is abnormal, the second instruction unit 422 instructs the single-motor fan that has no abnormality in the dual-motor fan to operate using a preset compensation strategy. In this embodiment, the preset compensation strategy is a strategy for performing performance compensation for a single-motor fan that has no abnormality to normal performance of a dual-motor fan.

The preset compensation strategy includes: superimposing the duty cycle of the single-motor fan under normal performance with a preset compensation duty cycle to obtain a compensated duty cycle; and running the single-motor fan with no abnormality in the dual-motor fan with the compensated duty cycle, that is, the compensated duty cycle PWM2=the duty cycle PWM1 of the single-motor fan under normal performance+preset compensation duty cycle A. The preset compensation duty cycle A is 20%-40% of the duty cycle under normal performance. The value of the preset compensation duty cycle A can be optimized and adjusted according to different fan sizes, models, systems, etc., to achieve better results.

It should be noted that the division of each module of the above system is only a division of logical functions. In actual implementation, the modules may be integrated into one physical entity in whole or in part, or may be physically separated. And these modules may all be implemented in the form of processing component calling by software, or they may all be implemented in the form of hardware. It is also possible that some modules are implemented in the form of processing component calling by software, and some modules are implemented in the form of hardware. For example, an x module may be a separate processing component, or may be integrated in a chip of the above-mentioned system. In addition, the x module may also be stored in the memory of the above system in the form of program code. The function of the above x module is called and executed by a processing component of the above system. The implementation of other modules is similar. All or part of these modules may be integrated or implemented independently. The processing elements described herein may be an integrated circuit with signal processing capabilities. In the implementation process, each operation of the above method or each of the above modules may be completed by an integrated logic circuit of hardware in the processor element or an instruction in a form of software. The above modules may be one or more integrated circuits configured to implement the above method, such as one or more Application Specific Integrated Circuits (ASICs), one or more Digital Signal Processors (DSPs), or one or more Field Programmable Gate Arrays (FPGAs). When one of the above modules is implemented in the form of calling program codes by a processing component, the processing component may be a general processor, such as a Central Processing Unit (CPU) or other processors that may call program codes. These modules may be integrated and implemented in the form of a system-on-a-chip (SOC).

### Embodiment 3

This embodiment provides a server, which includes: a plurality of dual-motor fans for dissipating heat of the server, a processor, a memory, a transceiver, a communication interface or/and a system bus. The memory and communication interface are coupled with the processor and the transceiver through the system bus to achieve mutual communication. The memory stores computer programs, the communication interface communicates with other devices, and the processor and transceiver run computer programs to enable the server to perform the operations of the fan management method as described in Embodiment 1.

The system bus mentioned above may be a Peripheral Component Interconnect (PCI) bus or an Extended Industry Standard Architecture (EISA) bus, etc. The system bus can be divided into address bus, data bus, control bus and so on. For convenience of representation, only a thick line is used in the figure, but it does not mean that there is only one bus or one type of bus. The communication interface is used to implement communication between the database access device and other devices (such as a client, a read-write library, and a read-only library). The memory may include Random Access Memory (RAM), or may also include non-volatile memory, such as at least one disk memory.

The above processor may be a general processor, including a Central Processing Unit (CPU), a Network Processor (NP), and the like. It may also be a Digital Signal Processor (DSP), an Application Specific Integrated Circuit (ASIC), a Field-Programmable Gate Array (FPGA), or other programmable logic devices, discrete gate or transistor logic devices, or discrete hardware components.

The protection scope of the fan management method as described in the present disclosure is not limited to the sequence of operations listed in this embodiment. Any scheme realized by adding or subtracting operations or replacing operations of the traditional techniques according to the principle of the present disclosure is included in the protection scope of the present disclosure.

The present disclosure further provides a fan management system. The fan management system may implement the fan management method as described in the present disclosure. However, the realizing device of the fan management method as described in the present disclosure is not limited to the structure of the fan management system as listed in this embodiment. Any structural deformation and replacement of traditional techniques made according to the principle of the present disclosure are included in the protection scope of the present disclosure.

In summary, the fan management method and system, and the server of the present disclosure have the following beneficial effects:

First, the present disclosure can reduce energy consumption of the server, avoid waste, and save operating costs.

Second, the present disclosure can reduce server noise and improve user experience.

Third, the present disclosure can prevent the fan of server from running at a high speed for a long time and improve the service life of the fan. The present disclosure effectively overcomes various shortcomings and has high industrial utilization value.

The above-mentioned embodiments are just used for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

We claim:

1. A fan management method, wherein the method is applied to a server, and the server includes a plurality of dual-motor fans; wherein the method comprises:
monitoring working performance of each of the plurality of dual-motor fans in real-time; and
determining whether the working performance of the dual-motor fan is normal, if the working performance is normal, instructing the dual-motor fan to continue to operate with normal performance; if the working performance is not normal, instructing a single-motor fan that has no abnormality in the dual-motor fan to operate with a preset compensation strategy; the preset compensation strategy is a strategy for performing performance compensation for a single-motor fan that has no abnormality to normal performance of a dual-motor fan.

2. The fan management method according to claim 1, wherein the working performance of the dual-motor fan includes a speed and/or a duty cycle of the single-motor fan in the dual-motor fan.

3. The fan management method according to claim 2, wherein said monitoring of the working performance of the dual-motor fan in real-time comprises:
monitoring an ambient temperature and a temperature of an internal component of the server in real-time by a management unit of the server; and
calculating a speed of the dual-motor fan according to the ambient temperature and the temperature of the internal component of the server by the management unit of the server.

4. The fan management method according to claim 3, wherein the internal component of the server includes a processor, a memory, and a dual in-line memory module.

5. The fan management method according to claim 3, wherein a method for calculating the speed of the single-motor fan comprises:
any one or a combination of a linear speed control method and a proportional-integral-derivative speed control method.

6. The fan management method according to claim 3, wherein said determining of whether the working performance of the dual-motor fan is normal comprises:
comparing the speed of each single-motor fan in the dual-motor fan with a preset speed threshold; when the speed of each single-motor fan is greater than the preset speed threshold, the working performance of the dual-motor fan is normal; when the speed of a single-motor fan is less than or equal to the preset speed threshold, the working performance of the dual-motor fan is abnormal.

7. The fan management method according to claim 2, wherein the preset compensation strategy comprises:
superimposing the duty cycle of the single-motor fan under normal performance with a preset compensation duty cycle to obtain a compensated duty cycle; and
running the single-motor fan with no abnormality in the dual-motor fan with the compensated duty cycle.

8. The fan management method according to claim 7, wherein the preset compensation duty cycle is 20%-40% of the duty cycle under normal performance.

9. A fan management system, wherein the system is applied to a server; the system comprises:
a management module, configured to monitor working performance of each of the plurality of dual-motor fans in real-time; and
a processing module, configured to determine whether the working performance of the dual-motor fan is normal, if the working performance is normal, instructing the dual-motor fan to continue to operate with normal performance; if the working performance is not normal, instructing a single-motor fan that has no abnormality in the dual-motor fan to operate with a preset compensation strategy; the preset compensation strategy is a strategy for performing performance compensation for a single-motor fan that has no abnormality to normal performance of a dual-motor fan.

10. A server, comprising: a plurality of dual-motor fans for dissipating heat of the server, a processor, and a memory;
the memory stores a computer program, and the processor executes the computer program stored in the memory, causes the server to implement a fan management method applied to a server, and the server includes a plurality of dual-motor fans; wherein the method comprises:
monitoring working performance of each of the plurality of dual-motor fans in real-time; and
determining whether the working performance of the dual-motor fan is normal, if the working performance is normal, instructing the dual-motor fan to continue to operate with normal performance; if the working performance is not normal, instructing a single-motor fan that has no abnormality in the dual-motor fan to operate with a preset compensation strategy; the preset compensation strategy is a strategy for performing performance compensation for a single-motor fan that has no abnormality to normal performance of a dual-motor fan.
